(19) United States
(12) Patent Application Publication
(10) Pub. No.: US 2016/0079055 A1
(43) Pub. Date: Mar. 17, 2016

(54) SAMPLE CLEANING APPARATUS AND SAMPLE CLEANING METHOD

(71) Applicant: Hitachi High-Technologies Corporation, Tokyo (JP)

(72) Inventors: Naoyuki KOFUJI, Tokyo (JP); Tadamitsu KANEKIYO, Tokyo (JP); Kazunori SHINODA, Tokyo (JP); Junichi TANAKA, Tokyo (JP)

(73) Assignee: HITACHI HIGH-TECHNOLOGIES CORPORATION

(21) Appl. No.: 14/625,898

(22) Filed: Feb. 19, 2015

(30) Foreign Application Priority Data
Sep. 12, 2014 (JP) 2014-185849

(51) Int. Cl. H01L 21/02; B08B 7/02; B06B 3/00

(52) U.S. Cl. CPC H01L 21/02068; B06B 3/00; B08B 7/028

(57) ABSTRACT

A sample cleaning apparatus includes a vibrating unit which ultrasonically vibrates a sample while the sample is mounted and held on a sample stage arranged in a processing chamber, the vibrating unit including: a dielectric film which is arranged on the sample stage and above which the sample is mounted; electrodes which are arranged adjacent to each other in the dielectric film; and a radio frequency power supply which supplies radio frequency power at frequencies in a prescribed range to the electrodes while the sample is hold on the sample stage; and a gas supply unit which forms a gas flow in a direction along a surface of the sample, so that particles are expelled.

### BACKGROUND OF THE INVENTION

The present invention relates to an apparatus and a method for cleaning a substrate-like sample such as a semiconductor wafer and, particularly, to an apparatus and a method for removing fine particles adhering to a top surface of the sample mounted on a sample stage within a processing chamber that is adjusted to have a prescribed pressure value by supplying a gas.

With miniaturization in terms of circuit dimensions of semiconductor devices in recent years, a problem has emerged that when the fine particles adhering to the top surface of a semiconductor wafer, where the circuits of the semiconductor devices are formed by processing thin-film layers on the top surface, are removed by performing cleaning with liquid chemicals (wet cleaning), a wall portion between neighboring grooves in a circuit pattern formed by fabrication of a film structure which is configured of a plurality of thin-film layers on the top surface collapses due to surface tension of the liquid chemicals, and yield in manufacturing of semiconductor devices is impaired. In order to work around the problem, technologies for dry cleaning have been proposed to remove the particles without using the liquid chemicals.

As an example of the above prior art, the technology disclosed in, for example, JP-A-H07-096259 is known. According to the technology disclosed in JP-A-H07-096259, by vibrating a wafer while a shock wave is intermittently radiated to the wafer from a shock wave source arranged on a ceiling surface of a processing chamber opposite to the top surface of the wafer mounted on a wafer stage arranged in the processing chamber and ultrasonic waves of 30 KHz to 2 MHz are generated from an ultrasonic transducer arranged within the wafer stage, particles are separated from the wafer to float in space within the processing chamber, and in this state a gas can be supplied along a plane direction of the top surface of the wafer from a gas supply port arranged in a side wall of the processing chamber so that the particles are carried by a flow of the gas to be expelled from the processing chamber together with the gas.

### SUMMARY OF THE INVENTION

However, the above-described prior art has problems because the following aspects were not considered sufficiently.

Namely, with the technology disclosed in JP-A-H07-096259, it is likely to destroy fine patterns by the shock waves radiated from the upper part within the processing chamber when a wafer on which fine circuit patterns are formed is cleaned. On the other hand, when the particles are tried to be separated from the top surface of a wafer only by applying ultrasonic waves without radiating a shock wave according to the prior art, a possibility of destroying circuit patterns is reduced, but there occurs a problem that fine particles cannot be removed substantially.

As described above, the prior art hardly satisfies both suppression of breakage of the circuit patterns and performance of removal of the particles when the wafer top surface is cleaned, and the problem that a yield of semiconductor device manufacturing is impaired in either case has not been considered in the prior. An object of the present invention is to provide a sample cleaning apparatus and cleaning method that can prevent impairment of the yield.

The inventors have obtained knowledge through studies that, when a sample is cleaned by applying ultrasonic waves to the sample arranged within a processing chamber and also forming a gas flow within the processing chamber, particles are not fully removed from the top surface of the sample because the ultrasonic waves are not transmitted to the sample. The present invention was achieved on the basis of the above knowledge and has a feature that a wafer is ultrasonically vibrated efficiently by an alternating electric field to separate fine particles from the sample into space within the processing chamber and the separated particles are exhausted out of the processing chamber with a gas flow formed within the processing chamber.

More specifically, the above object is achieved by a sample cleaning apparatus, including a vibrating unit which ultrasonically vibrates a sample while the sample is mounted and held on a sample stage arranged within a processing chamber, the vibrating unit including: a dielectric film which is arranged on the sample stage and above which the sample is mounted; first and second electrodes which are arranged electrically isolated from each other and adjacent to each other in the dielectric film; and a radio frequency power supply which supplies radio frequency power at frequencies in a prescribed range to the first and second electrodes while the sample is held on the sample stage; and a gas supply unit which forms a gas flow above the sample, in a direction along a surface of the sample, within the processing chamber so that particles, which are liberated from the surface of the sample, are expelled using the gas flow

Otherwise, it is achieved by a sample cleaning method, including the steps of: ultrasonically vibrating a sample to be cleaned while the sample is mounted and held on a sample stage arranged within a processing chamber by supplying radio frequency power at frequencies in a prescribed range to first and second electrodes, which are arranged electrically isolated from each other and adjacent to each other in a dielectric film which is arranged on the sample stage and above which the sample is mounted, while the sample is held on the sample stage; and forming a gas flow in a direction along a surface of the sample by supplying a gas into the processing chamber above the sample and by exhausting the processing chamber, to expel particles liberated from the sample surface.

When the sample cleaning apparatus of the present invention is used, the particles can be removed efficiently, and collapse of the circuit patterns and impairment of a yield are prevented, which are caused by wet cleaning of the sample.

Other objects, features, and advantages or the invention will become apparent from the following description of the embodiments of the invention taken in conjunction with the accompanying drawings.

### BRIEF DESCRIPTION OF THE DRAWINGS

FIG. 1 is a longitudinal sectional view schematically illustrating an outline of a construction of a sample cleaning apparatus according to an embodiment of the present invention;

FIG. 2 is a longitudinal sectional view showing in a magnified fashion a schematic of the construction of a wafer stage of the embodiment shown in FIG. 1;

FIG. 3 is a longitudinal sectional view schematically showing in a magnified fashion portions of contacts between a wafer and the wafer stage in the embodiment shown in FIG. 1;

FIG. 4 is a graph showing a particle removal rate when a wafer is cleaned using the wafer stage according to the embodiment shown in FIG. 2;

FIG. 5 is a longitudinal sectional view schematically illustrating an outline of a construction of a modified embodiment of the wafer stage shown in FIG. 2;

FIG. 6 is a longitudinal sectional view schematically showing in a magnified fashion portions of contacts between the wafer and the wafer stage of a modified embodiment of the embodiment shown in FIG. 1;

FIG. 7 is a graph showing changes in the particle removal rate with respect to a depth of grooves in the surface of a dielectric film with a frequency of radio frequency power as a parameter in the modified embodiment shown in FIG. 6;

FIG. 8 is a longitudinal sectional view schematically illustrating a shape of a circuit pattern formed in advance on the top surface of the wafer cleaned in the embodiment shown in FIG. 1;

FIG. 9 is a graph showing a change in voltage of the radio frequency power that causes a circuit pattern to collapse with respect to a height of the pattern in the embodiment shown in FIG. 1;

FIG. 10 is a longitudinal sectional view schematically illustrating an outline of a construction of a modified embodiment provided with a structure for detecting a change in capability of particle removal in the sample cleaning apparatus according to the embodiment shown in FIG. 1;

FIG. 11 is a longitudinal sectional view schematically illustrating a construction of a sample cleaning apparatus according to prior art; and

FIG. 12 is a graph showing a change in the particle removal rate on the top surface of the wafer with respect to a size in the diameter of the particles.

### DESCRIPTION OF THE EMBODIMENTS

Embodiments of the present invention are described below with reference to the drawings.

The inventors have studied about conditions necessary for separation of particles from the top surface of a semiconductor wafer only by vibrating the semiconductor wafer made of silicon, which is a substrate-like sample to be cleaned. It is presumed that whether or not the particles are separated from the wafer depends on a balance between a separation force F_{L} generated on the particles and an attraction force F_{A} of the particles to the wafer.

When the water is vibrated, the separation force represented by the following formula is generated to a particle by its inertia:

$${F}_{L} = \frac{2 {π}^{3}}{3} {d}^{3} ρ {af}^{2} \qquad ( 1 )$$

where F_{L} is an inertia force acting on the particle in N, ρ is the density of the particle in Kg/m³, a is the amplitude of the ultrasonic vibration in m, ƒ is the frequency in Hz, and d is the diameter of the particle in m.

On the other hand, an attraction force due to the van der Waals force is generated on the particles on the wafer, and its magnitude is represented by the following formula:

$${F}_{A} = \frac{Ad}{6 {H}_{0}^{2}} \qquad ( 2 )$$

where F_{A} is the attraction force acing on a particle in N, H₀ is the surface roughness of the wafer in m, and A is Hamaker constant in J.

For separation of particles from the wafer, the separation force F_{L} must become larger than the attraction force F_{A}, so that the condition under which the particles are separated from the wafer by vibration is represented by the following formula:

$${af}^{2} > \frac{A}{4 {π}^{3} ρ {H}_{0}^{2} {d}^{2}} \qquad ( 3 )$$

Specifically, when particles have a smaller diameter (particle diameter), the vibrations are required to have a larger amplitude and a higher frequency. In the manufacturing process of semiconductor devices, the particles which cause problems such as wafer contamination, damage to a device, and deterioration of performance are currently considered to have particle diameters of 100 nm or less; therefore, in the cleaning for removal of the particles without depending on the chemical liquid, capability of removing the particles having a particle diameter of at least 100 nm is required. Here, it was presumed that alumina particles are adsorbed on a silicon wafer, and a value af² was studied as a technical requirement necessary for removal of the particles having a particle diameter of 100 nm.

As a result, the magnitude of af², which is the inertia (acceleration) necessary for removal of the particles, became 2.36×10⁸ m/s². The amplitude needed to realize the above value becomes 26 cm for the minimum frequency of 30 KHz in the frequency range of the vibration disclosed in JP-A-H07-096259, and it becomes 60 μm when the highest frequency of 2 MHz is used. On the other hand, the amplitude which can be generated with the ultrasonic transducer is 70 μm at most. Therefore, the highest frequency of 2 MHz in the frequency range of the ultrasonic vibration in JP-A-H07-096259 was used to detect the removal rate by actually performing removal of particles having a fine particle diameter.

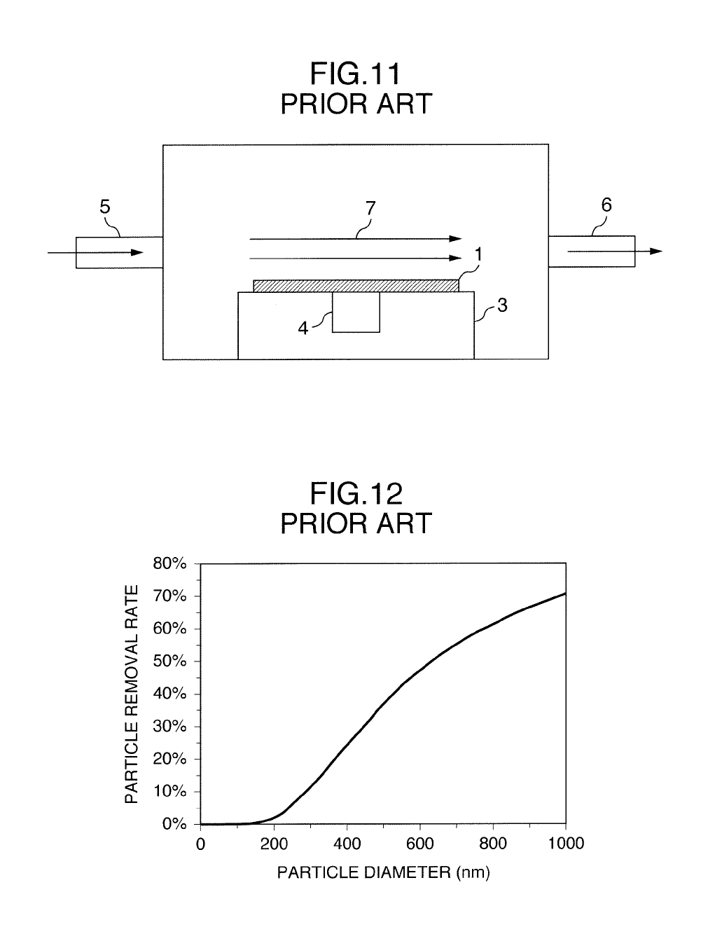

For the above detection, a sample cleaning apparatus according to the prior art shown in FIG. 11 was used. FIG. 11 is a longitudinal sectional view schematically showing a construction of the sample cleaning apparatus according to the prior art.

In the apparatus shown in the figure, a wafer stage 3 disposed on a lower portion in a processing chamber within a processing vessel has an ultrasonic transducer 4 attached therein, and ultrasonic vibration of an amplitude of 70 μm at a frequency of 2 MHz can be supplied to the top surface of the wafer stage 3 by vibrations of the ultrasonic transducer 4. Further, a wafer 1 is held to adhere on the top surface of the wafer stage 3 by a vacuum chuck mechanism so that it is configured that the wafer 1 does not displace on or drop from the wafer stage 3 even when ultrasonic waves are applied to the wafer stage 3.

In the apparatus, while a nitrogen gas of 20 slm (standard liters per minute) is supplied into the processing chamber from a gas supply port 5 which is arranged in a side wall of the processing chamber and above the top surface of the wafer stage 3 within the processing vessel, the gas in the processing chamber is exhausted through an exhaust port 6 which is arranged in a side wall of the processing chamber on the side opposite to the gas supply port 5 with the wafer stage 3 between them. A steady gas flow 7 is thus generated along the surface of the wafer 1, the particles are separated from the top surface of the wafer by vibration with ultrasonic waves, and the particles being floated in the processing chamber are carried by the steady gas flow 7 and exhausted out of the processing chamber, thereby cleaning the top surface of the wafer 1. Meanwhile, the processing chamber had a pressure of 75 kPa at this time.

The result of evaluation of particle removal on the top surface of the wafer 1 (opposite to the processing chamber inner wall) using the apparatus is described with reference to FIG. 12 with the particle diameter of the particles on the abscissa and the removal rate on the ordinate. FIG. 12 is a graph showing a change in the particle removal rate on the top surface of the wafer with respect to the particle diameter.

It is seen as shown in the figure that a removal rate (a ratio of the number of reduction of particles after the cleaning to the number of particles on the wafer before mounting onto the wafer stage) of particles of 200 nm or less is 5% or less according to the above construction of the apparatus, and the particles cannot be removed substantially. The inventors made studies on the cause that the particles could not be removed, and it was found as a result that when ultrasonic waves are applied to the wafer stage 3 or the wafer 1, the wafer 1 partly floated up from the top surface of the wafer stage 3 and vibrations of the wafer stage 3 by the ultrasonic waves are substantially not transmitted to the wafer 1.

The inventors thought that the wafer 1 floated because a force larger than the attraction force (e.g., 0.1 MPa) of the vacuum chuck was applied to the wafer 1. Then, a force generated in the wafer was estimated with the inertia force described above.

The inertia force generated in the wafer 1 by the vibration of ultrasonic waves is represented by the following formula:

P_{L}=4π²ρₛᵢd_{wαƒ}αƒ² (4)

where P_{L} is the inertia force generated in the wafer in Pa, ρₛᵢ is the density of silicon (2.33×10³ kg/m³), and d_{waf} is the thickness of the silicon wafer (0.775×10⁻³ for the wafer of the diameter of φ300 mm).

The magnitude of 2.36×10⁸ m/s² of the above-described af² is used and the inertia force calculated from the formula (4) becomes 17 MPa, which is a force 170 times larger than the attraction force of 0.1 MPa of the vacuum chuck. As a result of supply of vibrations of ultrasonic waves from the wafer stage 3, such the inertia force is generated in the wafer 1 and the wafer 1 temporarily floats partly from the wafer stage, so that a gap is generated between the wafer 1 and the wafer stage 3. It was found that the ultrasonic waves are reflected due to the gap and the wafer is not vibrated. As a result of the study, the gap described above was in the order of 10 μm.

In order to solve the problem that creation of the above gap causes to locally reduce the amplitude of the vibration of the wafer 1 and a prescribed inertia force cannot be generated, thereby resulting in insufficient removal of particles, the inventors have devised a construction of vibrating the wafer directly by an electric field.

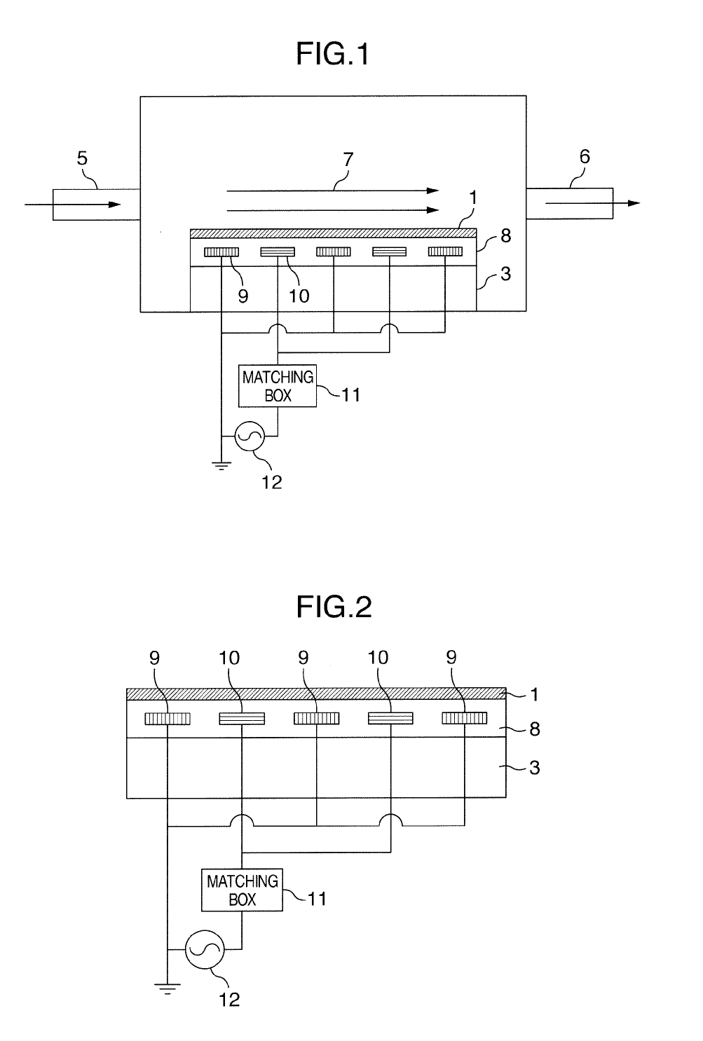

An embodiment of the present invention is described below with reference to FIGS. 1 to 4.

A sample cleaning apparatus of FIGS. 1 to 4 has a construction similar to that shown in FIG. 11 and is provided in the processing chamber arranged within a vacuum vessel with the wafer stage 3 which has the wafer 1 held on its top surface.

Specifically, FIG. 1 is a longitudinal sectional view schematically illustrating an outline of the construction of the sample cleaning apparatus according to the embodiment of the present invention. The apparatus shown in FIG. 1 is provided with a processing vessel which has a processing chamber disposed therein, the wafer stage 3 which is arranged at a lower part of the processing chamber, which provides a space inside of which the wafer 1 is arranged, and holds the wafer 1 thereon, the gas supply port 5 which is an opening arranged in a side wall of the processing chamber and through which a gas is introduced into the processing chamber, and the exhaust port 6 which is an opening arranged in an inner wall of the processing chamber on the opposite side of the gas supply port 5 with the top surface of the wafer stage 3 between them and through which the gas is exhausted out of the processing chamber.

The wafer stage 3 of the present embodiment is a member having a cylindrical or disc shape or a shape substantially the same as them and arranged at a lower part of the processing vessel. The upper part of the wafer stage 3 is configured to have a film which is formed by thermal spraying a dielectric material such as ceramics like alumina or yttria, or a sintered member of a small thickness made of it, and a dielectric film 8 is arranged on the top surface of it to place the wafer 1 thereabove. The top surface of the dielectric film 8 having a round shape of the wafer stage 3 or a shape substantially the same as it has a shape conforming to the circular wafer I and constitutes a mounting surface on which the wafer 1 is mounted.

In addition, the dielectric film 8 is supplied therein with electrodes 9 and electrodes 10 of circular or ring shapes which are arranged with gaps between the adjacent ones in a radial direction from a position corresponding to the center of the wafer 3, and two different voltages are applied to them, respectively. The electrodes 9, 10 are arranged electrically isolated from each other and applied with a different polarity or voltages. In the present embodiment, the electrodes 9 are grounded or electrically connected to another member which is set at a ground potential, and an RF power supply 12 is arranged between and connected to the electrodes 9 and the electrodes 10 via a matching box 11. With this configuration, an RF voltage from the RF power supply 12 is applied to these electrodes.

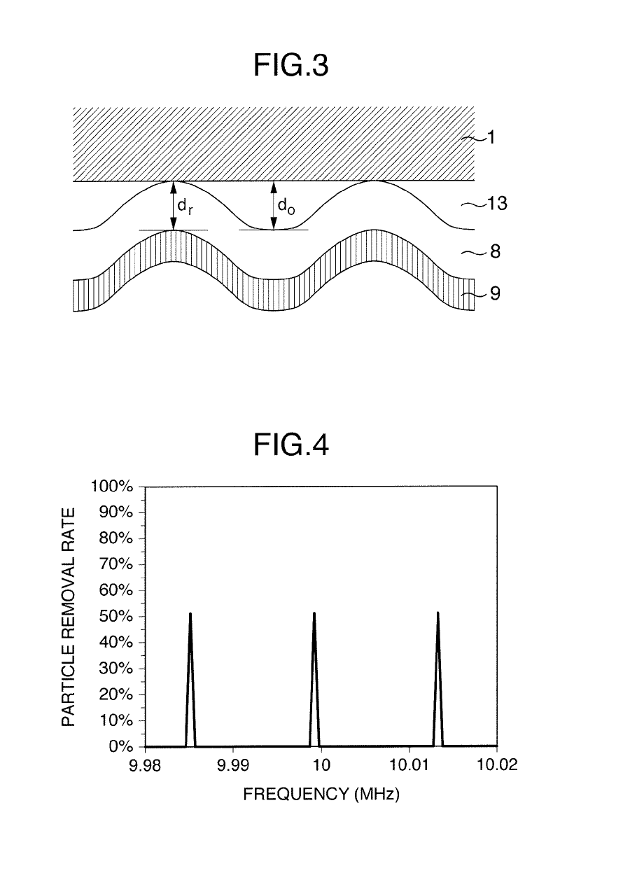

Referring to FIG. 3, transmission of vibrations between the wafer 1 and the dielectric film 8 occurring on the wafer stage 3 is described. FIG. 3 is a longitudinal sectional view schematically showing in a magnified fashion portions of contacts between the wafer and the wafer stage in the embodiment shown in FIG. 1.

The surface of the dielectric film 8 has unevenness representing roughness of the shape. Due to the unevenness, the portions of contacts between the wafer 1 and the dielectric film 8 have gaps 13 between the wafer 1 and the surface of the dielectric film 8 as shown in FIG. 3. Letting the distance between the wafer 1 and the dielectric film 8 at the gap portion be d₀ and the thickness of the dielectric film 8 between the electrode 9 and the wafer 1 be dᵣ, the attraction force represented by the following formula is generated between the wafer 1 and the dielectric film 8:

$${P}_{a} = {ɛ}_{0} {\vert E \vert}^{2} = {ɛ}_{0} \frac{{V}_{a}^{2} {cos}^{2} ω t}{{( {d}_{0} + \frac{{d}_{r}}{\text{?}} )}^{2}} = {ɛ}_{0} \frac{{V}_{a}^{2} ( 1 - cos 2 ω t )}{2 {( {d}_{0} + \frac{{d}_{r}}{\text{?}} )}^{2}} \\ \text{?} \text{indicates text missing or illegible when filed} \qquad ( 5 )$$

where Pa is the attraction force generated by the electric field in Pa, εᵣ is the relative dielectric constant of the dielectric film, ε₀ is the dielectric constant of vacuum in F/m, E is the electric field strength in V/m, Vₐ is the amplitude of the applied voltage in V, ω is the angular frequency in Hz, and t is time in s.

Specifically, it is seen from the formula (5) that the attraction force acting on the wafer 1 changes (alternates) its direction at a cycle twice that of the applied RF voltage with time. By this alternating attraction force, the wafer 1 is displaced in a direction increasing the distance (mutually separating) and a direction decreasing the distance (mutually pushing) and vibrated above the top surface of the dielectric film 8. Such vibrations are normally ultrasonic vibrations formed with a frequency which is in a band of ultrasonic waves (so-called ultrasonic range) exceeding the audible range of humans.

Using the construction of the wafer stage provided with the mechanism to generate such the ultrasonic waves, conditions under which particles can be removed were investigated. The construction of the wafer stage is described with reference to FIG. 2. FIG. 2 is a longitudinal sectional view showing in a magnified fashion a schematic of the construction of the wafer stage of the embodiment shown in FIG. 1.

In FIG. 2, the wafer stage 3 is equipped with a vacuum chuck, and the wafer 1 is held above the wafer stage 3 with it. And, in the present embodiment, alumina having a relative dielectric constant of 9.8 was used as the dielectric film 8, and the relation between the frequency of the RF power and the particle removal rate on the top surface of the wafer 1 was detected with the dielectric film between the electrode 9 and the wafer 1 having a thickness of 300 μm, an arithmetic average roughness Rₐ as the surface roughness of 9 μm, and the frequency of the RF power varied around 10 MHz. The results are shown in FIG. 4.

FIG. 4 is a graph showing a particle removal rate when the wafer is cleaned using the wafer stage according to the embodiment shown in FIG. 2. This figure shows changes of values with the frequency of the RF power on the abscissa and the particle removal rate on the ordinate. As shown in this figure, it is seen that the particle removal rate yields local maxima at respective frequencies of 9.985 MHz, 9.999 MHz, and 10.013 MHz of the RF power.

It was found from the results of analysis made by the inventors that resonance is caused by the vibration of ultrasonic waves of the wafer 1 at the above frequencies and the amplitude of vibration takes local maxima. On the other hand, when focus is directed to the particle removal rate at the respective local maximum points, their magnitudes are no greater than around 50%.

As a result of the study made on the cause by the inventors, it was found that the vibration of the wafer 1 has generated nodes of ultrasonic vibration concentrically in the radial direction from the center at an interval of 1.7 mm and particles remain on those portions since those portions hardly vibrate. And, it was also found that the distances of the nodes from the center of the wafer 1 vary depending on the frequency of the RF power.

Therefore, to solve the problem that the particles remain on the node portions, the particles were removed while sweeping the frequency of the RF power from 9.9 MHz to 10.1 MHz. As a result, it was found that the particle removal rate was improved up to 95%.

On the basis of the above knowledge, the frequency of the RF power generated by the RF power supply in the present embodiment is varied within a prescribed range in time while it is supplied to the electrodes 9, 10. Thus, the particles are prevented from locally remaining on the top surface of the wafer 1.

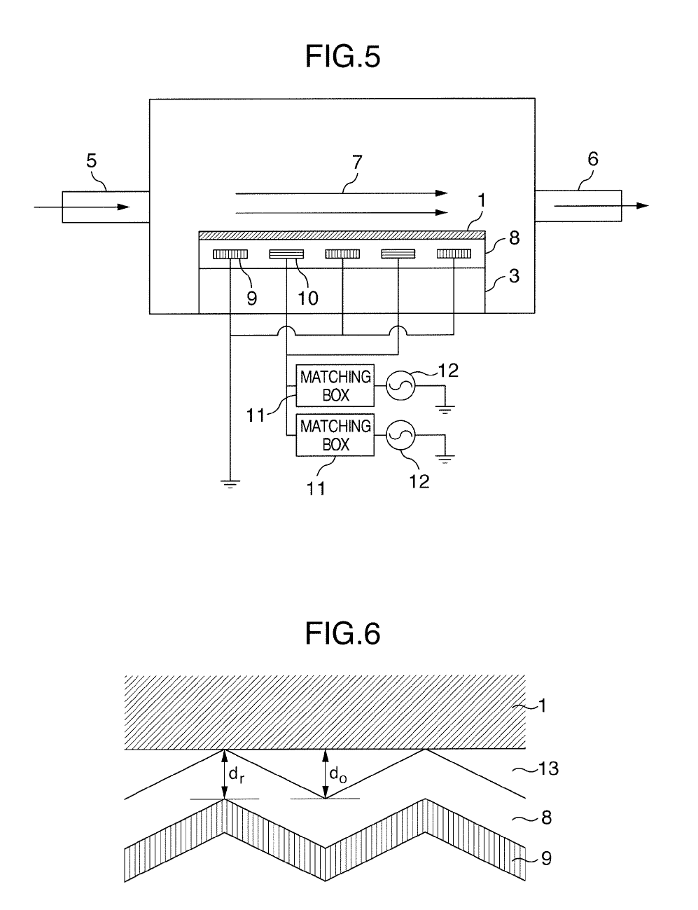

As another structure, two sets of the matching box and the power supply were used to remove particles as shown in FIG. 5 and the removal rates were detected FIG. 5 is a longitudinal sectional view schematically showing an outline of a construction of a modified embodiment of the wafer stage shown in FIG. 2. In this embodiment, the RF power supplied by two RF power supplies 12 has frequencies of 9.985 MHz and 10.013 MHz, and the voltages of the above RE frequencies are superposed and applied to between the electrodes 9 and the electrodes 10. With this configuration, there was also obtained a high particle removal rate of 95%.

By providing the wafer stage 3 having the above-described structure within the processing chamber, the sample cleaning apparatus of the embodiment prevents the particles from remaining on the wafer top surface as adhering locally and not separating, and the particles on the top surface of the wafer 1 can be reduced on the entirety of the top surface efficiently. Moreover, the above-described embodiments cover an example that the frequency of the RF power was made variable and an example that two sets of the matching box and the power supply were used and two kinds of RF voltages were superposed, but the same effects can be obtained by superposing two or more kinds of frequencies or by applying a RF voltage including two or more kinds of frequencies with an arbitrary waveform generator and an RF amplifier.

The inventors additionally studied on effects of the surface roughness onto the particle removal rate. In the study, grooves having a V shape viewed in a longitudinal cross section as shown in FIG. 6 were concentrically formed around the position corresponding to the center of the wafer 1 in the surface of the dielectric film 8. And, the distance between the electrode 9 or the electrode 10 and the back surface of the wafer 1, which was also thickness dᵣ of the dielectric film 8, was determined to be 300 μm. The depth d₀ of the V-shaped grooves of the wafer stage 3 was changed, and the change of the particle removal rate corresponding to the above change was detected. The construction of the wafer stage 3 is otherwise the same as that shown in FIG. 2.

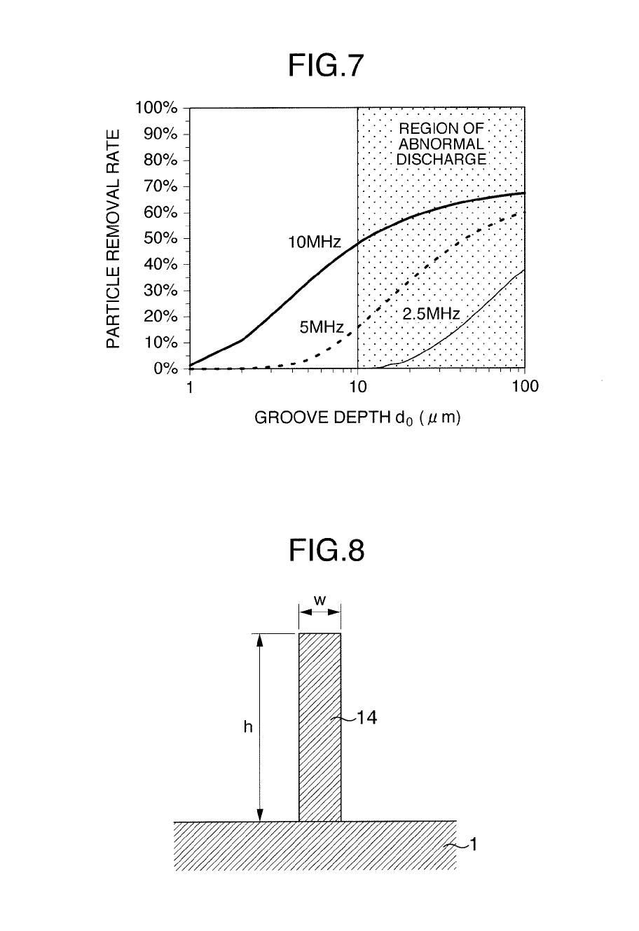

In the above study, RF powers of resonance frequencies near 2.5 MHz, 5 MHz, and 10 MHz from the RF power supply 12 were applied to the electrodes 9 or 10, and the particle removal rates for particles having a particle diameter of 100 nm were measured. The results are shown in FIG. 7.

FIG. 7 is a graph showing changes in the particle removal rate with respect to the depth of grooves in the surface of the dielectric film with the frequency of the RF power as a parameter in the modified embodiment shown in FIG. 6. As shown in the figure, it is seen that for the case of the frequency of around 2.5 MHz (the precise resonance frequency of 2.507 MHz), the particle removal rate increases rapidly when the groove depth is greater than 10 μm.

It is also seen that when the frequency of the RF power is increased to around 5 MHz (the precise resonance frequency of 5.014 MHz) and further to around 10 MHz (the precise resonance frequency of 10.013 MHz), a threshold value of the groove depth decreases inversely proportional to the square of the frequency. Furthermore, since the groove depth which becomes the above threshold value is inversely proportional to the square of the particle diameter of the object particles, it is considered that the necessary groove depth increases furthermore when the object particle diameter decreases along with miniaturization of semiconductor devices.

On the other hand, it was found that this method has a problem that when the groove depth is increased to greater than 10 μm, abnormal discharges occur on the back surface of the wafer. Therefore, the groove depth is desirably 10 μm or less. And, it is also seen that the RF power supplied to the electrodes 9, 10 must have a frequency of 2.5 MHz or more for removal of particles with the groove depth of 10 μm or less. Incidentally, although the example of FIGS. 6 and 7 shows the results of study on the concentrically formed grooves, the arrangement of the grooves in the dielectric film 8 may not be concentric; furthermore, the same results can be obtained by supplying a RF power of 2.5 MHz or more when recess portions are made to have a size of 10 μm or less by increasing the roughness of the surface by simply sandblasting or the like.

In addition, the inventors have made studies on a requirement that a circuit pattern formed on the wafer does not collapse. FIG. 8 is a longitudinal sectional view schematically illustrating a shape of the circuit pattern formed in advance on the top surface of the wafer cleaned in the embodiment of FIG. 1. Particles were removed from the wafer 1, on which a poly-silicon pattern 14 was formed on its top surface with a height h and a width w shown in FIG. 8 varied, using the sample cleaning apparatus of FIG. 1 while the frequency of the RF power supplied from the RF power supply 12 was changed and occurrence of collapse of the pattern was detected. From the measured results, the relation between the above dimensions of the pattern and the frequency of the voltage supplied from the RF power supply 12 was detected.

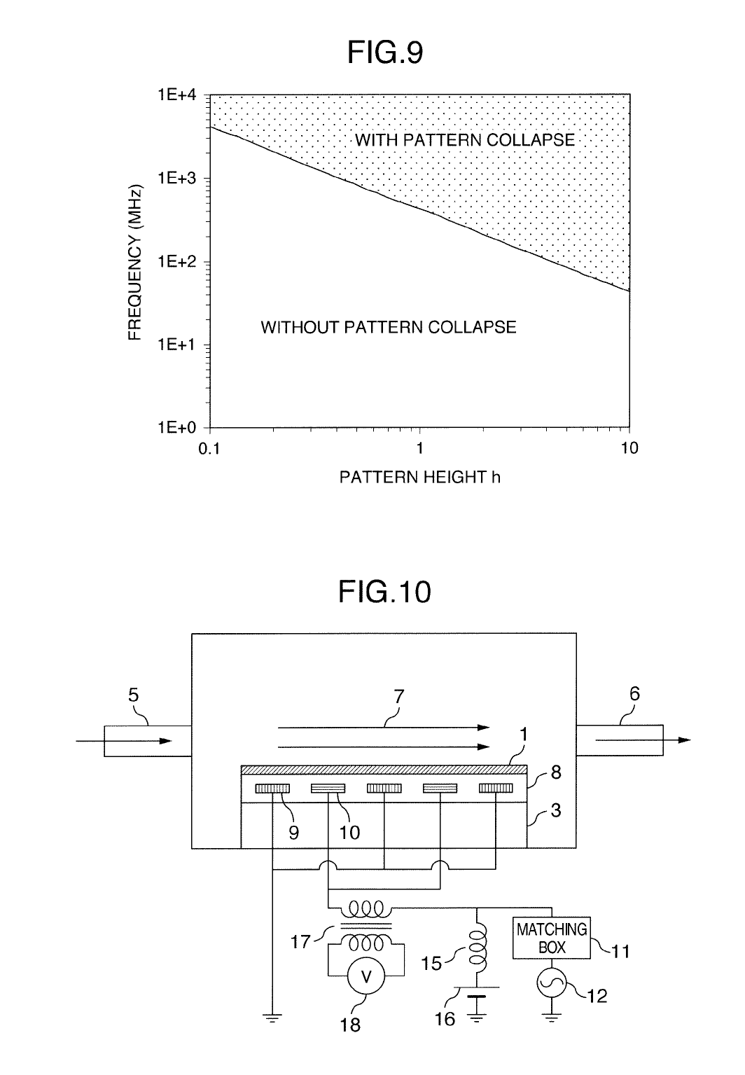

FIG. 9 shows the detected results. FIG. 9 is a graph showing a change in voltage of the RF power that causes the pattern collapse with respect to the height of the circuit pattern in the embodiment shown in FIG. 1. In the figure, the frequency (in MHz) is indicated on the ordinate, and the pattern height (in μm) is indicated on the abscissa.

First, it was found that the width w of the pattern hardly affects the pattern collapse. In addition, it was found that the height h of the pattern which collapses and the frequency of the RF power are in an inverse proportion relation to each other as shown in FIG. 9. In the current semiconductor device production, the height of the pattern formed on the wafer 1 is several hundreds of nm, and even a capacitor of DRAM, which has the largest height, has a height of several μm. Therefore, it was found that the used frequency is desirably suppressed to 100 MHz or less.

As described above, to prevent abnormal discharge on the back surface of the wafer, it is necessary that the RF power has a frequency of 2.5 MHz or more; therefore, in the semiconductor device production process, the particles can be removed effectively by using the RF power of the frequency in a range of 2.5 MHz or more and 100 MHz or less supplied from the RF power supply 12 in the sample cleaning apparatus of the present embodiment.

Referring to FIG. 10, a construction to detect the frequency enabling to maximize the particle removing capability is described. FIG. 10 is a longitudinal sectional view schematically illustrating an outline of the construction of a modified embodiment provided with the structure for detection of a change in capability of particle removal in the sample cleaning apparatus according to the embodiment shown in FIG. 1.

In the figure, a difference from the embodiment shown in FIG. 1 is the configuration of a power supply circuit which electrically connects the RF power supply 12 and the electrodes 10. The other structures are the same as those of the embodiment shown in FIG. 1. In the present embodiment, a DC power supply 16 is electrically connected in parallel with an output end of the matching box 11 via an inductor 15, and the other end of the DC power supply 16 is grounded.

The end of the matching box 11 is also connected to the electrode 10 via a transformer 17, and a voltmeter 18 for detecting a voltage formed across the transformer is connected to the secondary side of the transformer 17. Incidentally, the inductor 15 is connected between the transformer 17 and one end of the matching box 11. When the magnitude of the voltage supplied from the DC power supply 16 is amply larger than a Peak-to-Peak value of the voltage of the RF power from the RF power supply 12, the amplitude of the voltage generated on the secondary side of the transformer 17, which is detected by the voltmeter 18, is represented by the following formula:

$${V}_{m} ≅ - 4 {π}^{2} {af}^{2} \text{?} \\ \text{?} \text{indicates text missing or illegible when filed} \qquad ( 6 )$$

where S₀ is the area of the wafer in m², V₀ is the magnitude of the DC voltage in V, and L₁₂ is the mutual inductance of the transformer in H.

This value is proportional to the particle removing capability described with reference to the formula (3), so that the particle removing capability can be increased by adjusting the frequency to increase the amplitude. Based on the above fact, the frequency at which the particle removing capability becomes maximum or desirable is detected and selected, and by using the RF power of that frequency in the sample cleaning apparatus of FIG. 1, a high particle removal rate can be obtained.

Also, as another method, by arranging a laser type vibration measuring device on a ceiling surface, which is opposite to the top surface of the wafer 1, of the processing chamber of the sample cleaning apparatus shown in FIG. 1, detecting the magnitude of the amplitude while the ultrasonic transducer 4 is driven to vibrate the wafer 1, and varying the frequency of the RF power supplied from the RF power supply 12 to the electrodes 9, 10, the frequency at which the amplitude becomes maximum may be detected.

It should be further understood by those skilled in the art that although the foregoing description has been made on embodiments of the invention, the invention is not limited thereto and various changes and modifications may be made without departing from the spirit of the invention and the scope of the appended claims.

1. A sample cleaning apparatus, comprising:
a vibrating unit which ultrasonically vibrates a sample while the sample is mounted and held on a sample stage arranged within a processing chamber, the vibrating unit comprising:
a dielectric film which is arranged on the sample stage and above which the sample is mounted;
first and second electrodes which are arranged electrically isolated from each other and adjacent to each other in the dielectric film; and
a radio frequency power supply which supplies radio frequency power at frequencies in a prescribed range to the first and second electrodes while the sample is held on the sample stage; and
a gas supply unit which forms a gas flow above the sample, in a direction along a surface of the sample, within the processing chamber so that particles, which are liberated from the surface of the sample, are expelled using the gas flow.

2. The sample cleaning apparatus according to claim 1, wherein the prescribed range is 2.5 MHz or more and 100 MHz or less.

3. The sample cleaning apparatus according to claim 2, wherein the frequencies are varied within the prescribed range while the radio frequency power is supplied to the first and second electrodes to ultrasonically vibrate the sample.

4. The sample cleaning apparatus according to claim 2, wherein radio frequency power of a plurality of frequencies selected from resonance frequencies of the sample in the prescribed range is superposed and supplied to the first and second electrodes.

5. The sample cleaning apparatus according to claim 2, wherein the dielectric film has an average roughness of 10 μm or less on its surface.

6. A sample cleaning method, comprising the steps of:
ultrasonically vibrating a sample to be cleaned while the sample is mounted and held on a sample stage arranged within a processing chamber by supplying radio frequency power at frequencies in a prescribed range to first and second electrodes, which are arranged electrically isolated from each other and adjacent to each other in a dielectric film which is arranged on the sample stage and above which the sample is mounted, while the sample is held on the sample stage; and
forming a gas flow in a direction along a surface of the sample by supplying a gas into the processing chamber above the sample and by exhausting the processing chamber, to expel particles liberated from the sample surface.

7. The sample cleaning method according to claim 6, wherein the prescribed range is 2.5 MHz or more and 100 MHz or less.

8. The sample cleaning method according to claim 7, wherein the frequencies are varied within the prescribed range while the radio frequency power is supplied to the first and second electrodes to ultrasonically vibrate the sample.

9. The sample cleaning method according to claim 7, wherein radio frequency power of a plurality of frequencies selected from resonance frequencies of the sample in the prescribed range is superposed and supplied to the first and second electrodes.

10. The sample cleaning method according to claim 6, wherein the dielectric film has an average roughness of 10 μm or less on its surface.
